(19) United States
(12) Patent Application Publication
(10) Pub. No.: US 2012/0086041 A1
(43) Pub. Date: Apr. 12, 2012

(54) LED PACKAGE

(75) Inventor: Masaki Isogai, Fukuoka-ken (JP)

(73) Assignee: KABUSHIKI KAISHA TOSHIBA, Tokyo (JP)

(21) Appl. No.: 13/042,569

(22) Filed: Mar. 8, 2011

(30) Foreign Application Priority Data
Oct. 6, 2010 (JP) 2010-226320

(51) Int. Cl. H01L 33/62

(52) U.S. Cl. 257/99; 257/E33.066

(57) ABSTRACT

According to one embodiment, an LED package includes a first leadframe, a second leadframe, an anisotropic conductive film, an LED chip, and a resin body. The first leadframe and the second leadframe are mutually separated. The anisotropic conductive film is provided on the first leadframe and the second leadframe. The LED chip is provided on the anisotropic conductive film. The LED chip includes a first terminal and a second terminal provided on a face of the LED chip on the anisotropic conductive film side. The resin body is provided on the anisotropic conductive film to cover the LED chip. The first terminal is connected to the first leadframe via the anisotropic conductive film. The second terminal is connected to the second leadframe via the anisotropic conductive film.

### CROSS-REFERENCE TO RELATED APPLICATIONS

This application is based upon and claims the benefit of priority from the prior Japanese Patent Application No. 2010-226320, filed on Oct. 6, 2010; the entire contents of which are incorporated herein by reference.

### FIELD

Embodiments described herein relate generally to an LED (Light Emitting Diode) package.

### BACKGROUND

In a conventional LED package, an LED chip is mounted on a leadframe; and terminals of the LED chip are connected to the leadframe via wires. The wires are drawn out in loops above the LED chip; and the LED chip and the wires are sealed with a resin.

### BRIEF DESCRIPTION OF THE DRAWINGS

FIG. 1 is a perspective view illustrating an LED package according to a first embodiment;

FIG. 2 is a side view illustrating the LED package according to the first embodiment;

FIG. 3 is a plan view illustrating the LED package according to the first embodiment;

FIG. 4 is a cross-sectional view illustrating an LED package according to a second embodiment;

FIG. 5 is a side view illustrating an LED package according to a third embodiment;

FIG. 6 is a perspective view illustrating an LED package according to a fourth embodiment;

FIG. 7A is a cross-sectional view illustrating the LED package according to the fourth embodiment and FIG. 7B is a plan view illustrating a leadframe;

FIGS. 8A to 8C are cross-sectional views of processes, illustrating a method for manufacturing the LED package according to the fourth embodiment;

FIGS. 9A to 9C are cross-sectional views of processes, illustrating the method for manufacturing the LED package according to the fourth embodiment;

FIGS. 10A and 10B are cross-sectional views of processes, illustrating the method for manufacturing the LED package according to the fourth embodiment;

FIG. 11A is a plan view illustrating a leadframe sheet of the fourth embodiment and FIG. 11B is a partially enlarged plan view illustrating device regions of the leadframe sheet;

FIGS. 12A to 12H are cross-sectional views of processes, illustrating a formation method of a leadframe sheet of a first variation of the fourth embodiment; and

FIG. 13A is a plan view illustrating an LED package according to a second variation of the fourth embodiment and FIG. 13B is a cross-sectional view of FIG. 13A.

### DETAILED DESCRIPTION

In general, according to one embodiment, an LED package includes a first leadframe, a second leadframe, an anisotropic conductive film, an LED chip, and a resin body. The first leadframe and the second leadframe are mutually separated. The anisotropic conductive film is provided on the first leadframe and the second leadframe. The LED chip is provided on the anisotropic conductive film. The LED chip includes a first terminal and a second terminal provided on a face of the LED chip on the anisotropic conductive film side. The resin body is provided on the anisotropic conductive film to cover the LED chip. The first terminal is connected to the first leadframe via the anisotropic conductive film. The second terminal is connected to the second leadframe via the anisotropic conductive film.

Embodiments of the invention will now be described with reference to the drawings.

First, a first embodiment will be described.

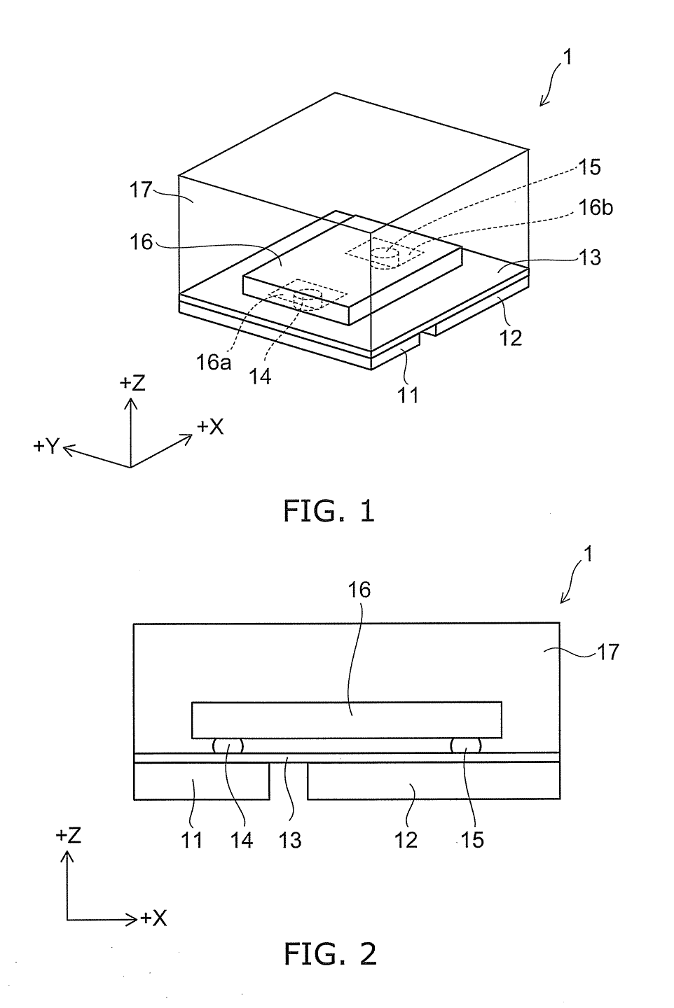

FIG. 1 is a perspective view illustrating the LED package according to this embodiment.

FIG. 2 is a side view illustrating the LED package according to this embodiment.

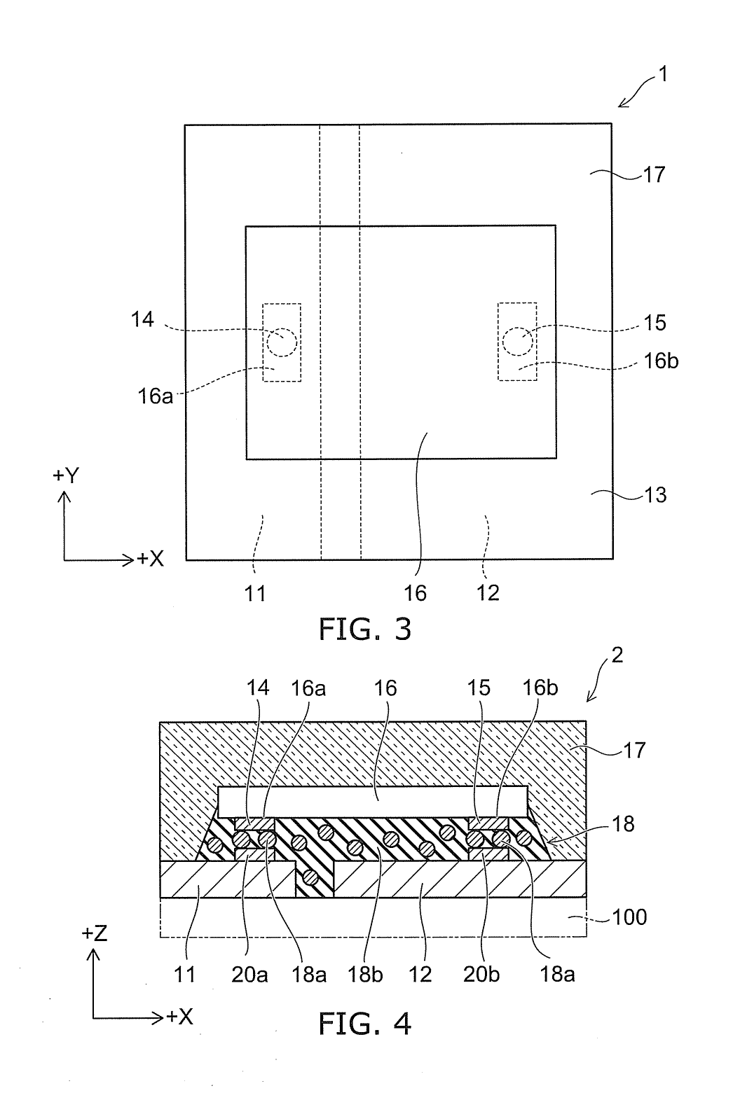

FIG. 3 is a plan view illustrating the LED package according to this embodiment.

A pair of leadframes 11 and 12 is provided in the LED package 1 according to this embodiment as illustrated in FIG. 1 to FIG. 3. The leadframes 11 and 12 are disposed in the same plane and are separated from each other.

Hereinbelow, an XYZ orthogonal coordinate system is introduced for convenience of description in the specification. A direction parallel to the upper faces of the leadframes 11 and 12 from the leadframe 11 toward the leadframe 12 is taken as a +X direction; and an upward direction perpendicular to the upper faces of the leadframes 11 and 12, i.e., a direction in which an LED chip 16 described below is mounted as viewed from the leadframes, is taken as a +Z direction; and one direction orthogonal to both the +X direction and the +Z direction is taken as a +Y direction. The directions opposite to the +X direction, the +Y direction, and the +Z direction are taken as a −X direction, a −Y direction, and a −Z direction respectively. The “+X direction” and the “−X direction,” for example, also are generally referred to as simply the “X direction.”

The leadframes 11 and 12 have flat plate configurations which are rectangular parallelepiped configurations. The lengths of the leadframes 11 and 12 in the Y direction are the same and are equal to the total length of the LED package 1. The lengths of the leadframes 11 and 12 in the Z direction, i.e., the thicknesses, also are the same. On the other hand, the lengths of the leadframes 11 and 12 in the X direction are different from each other; and the length of the leadframe 12 is longer than the length of the leadframe 11 in the X direction. The leadframes 11 and 12 are made of the same conductive material and include, for example, a silver plating layer formed on the upper face and the lower face of a copper plate. The silver plating layer is not formed and the copper plate is exposed at the end faces of the leadframes 11 and 12.

One layer of an anisotropic conductive film 13 is provided on the leadframes 11 and 12. The lengths of the anisotropic conductive film 13 in the X direction and the Y direction are equal to the total lengths of the LED package 1 respectively. In other words, the anisotropic conductive film 13 is disposed in the entire LED package 1 as viewed from above (the +Z direction).

In the anisotropic conductive film 13, conductive metal particles are dispersed in a film main body made of an insulating resin material. The film main body is made of, for example, a polyimide-based resin material and has a thickness of, for example, 15 to 30 μm. The metal particle is a particle in which a nickel layer, a gold layer, and a protective layer are stacked in this order around a core made of, for example, a resin. Thereby, an anisotropic electrical conductivity is realized in the anisotropic conductive film 13 in which current flows via the metal particles in the film thickness direction (the Z direction) and current does not flow in the film surface direction (the direction parallel to the XY plane) because the resin material is interposed between the metal particles.

A bump 14 is provided on the anisotropic conductive film 13 in a portion of the region directly above the leadframe 11. On the other hand, a bump 15 is provided on the anisotropic conductive film 13 in a portion of the region directly above the leadframe 12. The bumps 14 and 15 are formed of a conductive material having a low melting point such as, for example, gold or solder. The heights of the bumps 14 and 15 are about, for example, 40 to 50 μm.

The LED chip 16 is provided in a region including the region directly above the bumps 14 and 15. The LED chip 16 includes, for example, a semiconductor layer made of gallium nitride (GaN), indium gallium aluminum phosphorus (InGaAlP), etc., stacked on a transparent substrate such as a sapphire substrate. The LED chip 16 has, for example, a rectangular parallelepiped configuration. The LED chip 16 is disposed in a bridge-like configuration straddling the leadframe 11 and the leadframe 12. Terminals 16a and 16b are provided on the lower face of the LED chip 16, i.e., the face on the anisotropic conductive film 13 side. The terminal 16a is disposed in the region directly above the bump 14 and is bonded to the bump 14. The terminal 16b is disposed in the region directly above the bump 15 and is bonded to the bump 15. In the manufacturing processes of the LED package 1, the LED chip 16 to which the bumps 14 and 15 are bonded is bonded to the anisotropic conductive film 13 by pressurizing while heating. Thereby, the metal particles inside the anisotropic conductive film 13 are thermally bonded to each other to form a conduction path in the Z direction.

Thus, the terminal 16a of the LED chip 16 is connected to the leadframe 11 via the bump 14 and one portion of the anisotropic conductive film 13. The terminal 16b of the LED chip 16 is connected to the leadframe 12 via the bump 15 and one other portion of the anisotropic conductive film 13. Because the anisotropic conductive film 13 is insulative in the X direction, the terminal 16a is not connected to the leadframe 12 via the anisotropic conductive film 13 and the terminal 16b is not connected to the leadframe 11 via the anisotropic conductive film 13. Thus, the LED chip 16 is flip-chip mounted to the leadframes 11 and 12. The LED chip 16 emits, for example, blue light by a voltage being supplied between the terminal 16a and the terminal 16b.

A transparent resin body 17 is provided on the anisotropic conductive film 13. The transparent resin body 17 is formed of a transparent resin, e.g., a silicone resin; and the exterior form of the transparent resin body 17 is substantially a rectangular parallelepiped. The lower face of the transparent resin body 17 contacts the upper face of the anisotropic conductive film 13; and the transparent resin body 17 covers the upper face of the anisotropic conductive film 13, the bumps 14 and 15, and the LED chip 16. In the specification, the concept of covering includes both the case of being in contact with the covered component and the case of not being in contact with the covered component. Further, “being transparent” also includes being semi-transparent.

Many fluorescers (not illustrated) are dispersed in the interior of the transparent resin body 17. Each of the fluorescers has a granular configuration that absorbs the light emitted from the LED chip 16 and emits light having a longer wavelength. For example, the fluorescer absorbs a portion of the blue light emitted from the LED chip 16 and emits yellow light. Thereby, the LED package 1 emits the blue light that is emitted from the LED chip 16 and not absorbed by the fluorescer and the yellow light that is emitted from the fluorescer; and the emitted light emitted from the LED package 1 is white as an entirety.

The exterior form of the portion of the LED package 1 positioned above the anisotropic conductive film 13 is the exterior form of the transparent resin body 17. The exterior form of the portion of the LED package 1 positioned below the anisotropic conductive film 13 is the exterior form of the leadframes 11 and 12. The leadframes 11 and 12 are exposed at the lower face of the LED package 1.

Operational effects of this embodiment will now be described.

In the LED package 1 according to this embodiment, the anisotropic conductive film 13 is provided between the LED chip 16 and the leadframes 11 and 12. Thereby, the terminals 16a and 16b provided in the lower face of the LED chip 16 can be connected to the leadframes 11 and 12 via the anisotropic conductive film 13. As a result, because the LED chip 16 can be flip-chip mounted, it is unnecessary for wires to be provided above the LED chip 16 to connect the terminals of the LED chip 16 to the leadframes. Thereby, the light emitted from the LED chip 16 is not shielded by wires; and the LED package 1 has a high light extraction efficiency. Further, because wires are not provided, wires do not break due to the thermal stress of the transparent resin body 17. Also, because wires are not provided, wires do not interfere with each other.

Because the LED chip 16 is mounted on the leadframes 11 and 12 via the anisotropic conductive film 13 in this embodiment, the thermal stress acting between the LED chip 16 and the leadframes 11 and 12 can be mitigated by the anisotropic conductive film 13. Thereby, in the LED package 1 according to this embodiment, the risk that the current path between the LED chip 16 and the leadframes 11 and 12 being broken due to the thermal stress is low; and the reliability is high. Conversely, if the anisotropic conductive film 13 is not provided and the LED chip 16 is connected to the leadframes 11 and 12 via only the bumps 14 and 15, the thermal stress cannot be mitigated effectively and the reliability of the LED package decreases because the bumps 14 and 15 are formed of a metal material harder than the resin material.

In this embodiment, the anisotropic conductive film 13 is disposed in the entire region directly above the leadframes 11 and 12 and the entire region directly above the region between the leadframe 11 and the leadframe 12. Therefore, the resin material can be prevented from extending around below the leadframes 11 and 12 when the LED chip 16 and the like are buried in the resin material of the transparent resin body 17 prior to hardening.

Also in this embodiment, because the anisotropic conductive film 13 is disposed above the leadframes 11 and 12, the leadframes 11 and 12 can be exposed at the lower face of the LED package 1 to function as external electrodes with the anisotropic conductive film 13 left as-is. Thereby, a process to remove the anisotropic conductive film 13 is unnecessary; the manufacturing costs can be reduced; and the effects described above can be obtained by leaving the anisotropic conductive film 13. Further, the environmental impact is low because waste does not result from removing the anisotropic conductive film 13.

In this embodiment, the LED chips 16 can be mounted collectively for the pairs of leadframes 11 and 12. On the other hand, the wire bonding process can be omitted because the wires for connecting the leadframes to the LED chip are not provided. Thereby, the manufacturing process of the LED package 1 is simplified and the manufacturing costs can be reduced.

In this embodiment, light can be emitted in a wide range of angles because the exterior form of the upper portion of the LED package 1, i.e., the exterior form of the portion of the LED package 1 positioned above the anisotropic conductive film 13, includes the exterior form of the transparent resin body 17. Therefore, the LED package 1 according to this embodiment is advantageous when used in an application in which it is necessary for light to be emitted at a wide angle, e.g., illumination or the backlight of a liquid crystal television.

The anisotropic conductive film 13 may be formed of a silicone-based resin material. Thereby, the adhesion between the anisotropic conductive film 13 and the transparent resin body 17 can be increased because the anisotropic conductive film 13 is formed of the same type of material as the transparent resin body 17. A reflective filler may be mixed into the anisotropic conductive film 13. Thereby, the proportion of the light emitted from the LED chip 16 and the fluorescer that is reflected upward by the anisotropic conductive film 13 increases; and the light extraction efficiency increases even more.

A second embodiment will now be described.

FIG. 4 is a cross-sectional view illustrating the LED package according to this embodiment.

As illustrated in FIG. 4, the LED package 2 according to this embodiment differs from the LED package 1 (referring to FIG. 2) according to the first embodiment described above in that the anisotropic conductive film 13 (referring to FIG. 2) is not provided and an anisotropic conductive paste 18 is provided instead.

In the LED package 2, an electrode 20a is provided on the leadframe 11; and an electrode 20b is provided on the leadframe 12. The electrode 20a is disposed in the region directly under the bump 14; and the electrode 20b is disposed in the region directly under the bump 15. The electrode 20a and the bump 14 are separated from each other; and the electrode 20b and the bump 15 are separated from each other. The anisotropic conductive paste 18 is provided between the LED chip 16 and the conductive leadframes 11 and 12 in the entire region directly under the LED chip 16. The anisotropic conductive paste 18 contacts the lower face of the LED chip 16 and portions of the upper faces of the leadframes 11 and 12, covers the electrodes 20a and 20b and the bumps 14 and 15, and is interposed between the electrode 20a and the bump 14 and between the electrode 20b and the bump 15.

In the anisotropic conductive paste 18, metal particles 18b are dispersed in an insulative paste material 18a. Thereby, the anisotropic conductive paste 18 is electrically conductive in the Z direction and insulative in the X direction and the Y direction due to a principle similar to that of the anisotropic conductive film 13 described above. As a result, the electrode 20a is connected to the bump 14 via one portion of the anisotropic conductive paste 18; and the electrode 20b is connected to the bump 15 via one other portion of the anisotropic conductive paste 18. The anisotropic conductive paste 18 is interposed also between the leadframe 11 and the leadframe 12.

In the LED package 2, the transparent resin body 17 covers the anisotropic conductive paste 18. Thereby, the transparent resin body 17 covers a portion of the leadframe 11, a portion of the leadframe 12, and the LED chip 16 and covers the bumps 14 and 15 and the electrodes 20a and 20b with the anisotropic conductive paste 18 interposed therebetween. The exterior form of the upper portion of the LED package 2, i.e., the exterior form of the portion of the LED package 2 positioned above the leadframes 11 and 12, is the exterior form of the transparent resin body 17. Although a reinforcing tape 100 is illustrated in FIG. 4, the reinforcing tape 100 is adhered to the leadframes 11 and 12 in the manufacturing processes of the LED package 2, is subsequently peeled, and does not exist in the completed LED package 2 as described below. Otherwise, the configuration of this embodiment is similar to that of the first embodiment described above.

When manufacturing the LED package 2, a common reinforcing tape 100 is adhered to the lower faces of the leadframes 11 and 12; the electrodes 20a and 20b are formed on the leadframes 11 and 12; and the anisotropic conductive paste 18 is coated. Then, the LED chip 16, in which the bumps 14 and 15 are bonded to the terminals 16a and 16b, is pressed onto the anisotropic conductive paste 18. Thereby, the terminal 16a of the LED chip 16 is connected to the leadframe 11 via the bump 14, the metal particles 18b of the anisotropic conductive paste 18, and the electrode 20a. The terminal 16b of the LED chip 16 is connected to the leadframe 12 via the bump 15, the metal particles 18b, and the electrode 20b. Then, the paste material 18a of the anisotropic conductive paste 18 is hardened. Thereby, the LED chip 16 is fixed with respect to the leadframes 11 and 12. Then, the resin material is molded; the resin material is hardened; and the transparent resin body 17 is molded. Subsequently, the reinforcing tape 100 is peeled from the leadframes 11 and 12.

Operational effects of this embodiment will now be described.

In this embodiment, the LED chip 16 is flip-chip mounted to the leadframes 11 and 12 via the bumps 14 and 15, the anisotropic conductive paste 18, and the electrodes 20a and 20b. Therefore, similarly to the first embodiment described above, it is unnecessary for wires to be provided above the LED chip 16; and the light extraction efficiency is high. Also, wires do not break or interfere.

Also, in this embodiment, the LED chip 16 is mounted on the leadframes 11 and 12 via the anisotropic conductive paste 18 which is softer than the bumps 14 and 15. Thereby, the thermal stress acting between the LED chip 16 and the leadframes 11 and 12 can be mitigated by the anisotropic conductive paste 18. Therefore, the LED package 2 according to this embodiment has high reliability.

In this embodiment as well, similarly to the first embodiment described above, the exterior form of the upper portion of the LED package 2 includes the exterior form of the transparent resin body 17. Therefore, the light can be emitted toward a wide range of angles.

In the LED package 2 according to this embodiment, the silver plating layer is formed on the upper faces and the lower faces of the leadframes 11 and 12. Because the silver plating layer has a high optical reflectance, the LED package 2 according to this embodiment has a high light extraction efficiency.

The effects described above in which high reliability is provided will now be described based on specific test results.

### (1) Solder Reflow Test

Multiple samples were constructed by mounting the LED package 2 illustrated in FIG. 4 on a substrate (not illustrated) using solder. Then, these samples were humidified to saturation by exposing to an atmosphere having a temperature of 85° C. and a humidity of 85% for 3 hours. Continuing, each of the samples was heated twice to a temperature of 260° C. This heating simulates the reflow processing of the front surface and the back surface of the substrate. After the heating, a current was provided at room temperature and a temperature of 100° C.; and it was evaluated whether or not the samples turned on. As a result, there were samples that turned on even after being heated for reflow twice.

### (2) Thermal Stress Test

Multiple samples were constructed by mounting the LED package 2 illustrated in FIG. 4 on a substrate (not illustrated) using a conductive paste. Then, a thermal cycle test was performed on these samples by repeating a processing of maintaining a temperature of −40° C. for 30 minutes and a processing of maintaining a temperature of +100° C. for 30 minutes. As a result, there were samples that turned on even when 1000 cycles were exceeded.

### (3) High Temperature Bias Test

Samples were constructed by mounting the LED package 2 illustrated in FIG. 4 on a substrate (not illustrated) using a conductive paste. A current of 50 mA was provided continuously to these samples in an atmosphere having a temperature of 85° C. and a humidity of 85%. As a result, there were samples that turned on even when 500 hours were exceeded.

A third embodiment will now be described.

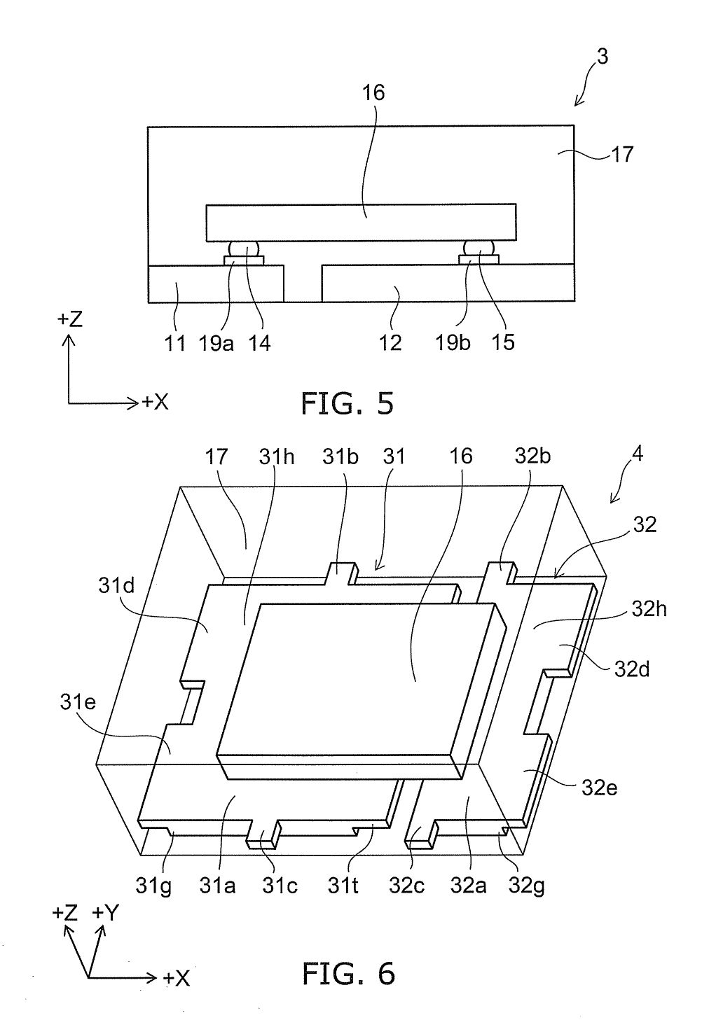

FIG. 5 is a side view illustrating the LED package according to this embodiment.

As illustrated in FIG. 5, the LED package 3 according to this embodiment differs from the LED package 1 (referring to FIG. 2) according to the first embodiment described above in that the anisotropic conductive film 13 (referring to FIG. 2) is not provided and conductive pastes 19a and 19b are provided instead. The conductive paste 19a is disposed on the leadframe 11 and connected to the lower portion of the bump 14; and the conductive paste 19b is disposed on the leadframe 12 and connected to the lower portion of the bump 15. Thereby, the terminal 16a of the LED chip 16 is connected to the leadframe 11 via the bump 14 and the conductive paste 19a; and the terminal 16b is connected to the leadframe 12 via the bump 15 and the conductive paste 19b. The conductive pastes 19a and 19b are conductive materials which are softer than the bumps 14 and 15, e.g., silver pastes.

In the LED package 3, the transparent resin body 17 is interposed also between the leadframe 11 and the leadframe 12. Thereby, the transparent resin body 17 also covers a portion of the leadframe 11 and a portion of the leadframe 12 in addition to the LED chip 16, the bumps 14 and 15, and the conductive pastes 19a and 19b. The exterior form of the upper portion of the LED package 3, i.e., the exterior form of the portion of the LED package 3 positioned above the leadframes 11 and 12, is the exterior form of the transparent resin body 17. Otherwise, the configuration of this embodiment is similar to that of the first embodiment described above.

When manufacturing the LED package 3, the common reinforcing tape 100 (referring to FIG. 4) is adhered to the lower faces of the leadframes 11 and 12; and the resin material is molded in this state. Thereby, the resin material enters into the gap between the leadframe 11 and the leadframe 12 to contact the reinforcing tape. Then, the resin material is hardened; and the transparent resin body 17 is molded. Subsequently, the reinforcing tape is peeled from the leadframes 11 and 12.

Operational effects of this embodiment will now be described.

In this embodiment, the LED chip 16 is flip-chip mounted to the leadframes 11 and 12 via the conductive pastes 19a and 19b and the bumps 14 and 15. Therefore, similarly to the first embodiment described above, it is unnecessary for wires to be provided above the LED chip 16; and the light extraction efficiency is high. Also, wires do not break or interfere.

In this embodiment, the LED chip 16 is mounted on the leadframes 11 and 12 via the conductive pastes 19a and 19b which are softer than the bumps 14 and 15. Thereby, the thermal stress acting between the LED chip 16 and the leadframes 11 and 12 can be mitigated by the conductive pastes 19a and 19b. Therefore, the LED package 3 according to this embodiment has high reliability.

In this embodiment as well, similarly to the first embodiment described above, the exterior form of the upper portion of the LED package 3 includes the exterior form of the transparent resin body 17. Therefore, the light can be emitted toward a wide range of angles.

In the LED package 3 according to this embodiment, the silver plating layer is formed on the upper faces and the lower faces of the leadframes 11 and 12. Because the silver plating layer has a high optical reflectance, the LED package 3 according to this embodiment has a high light extraction efficiency.

A fourth embodiment will now be described.

FIG. 6 is a perspective view illustrating the LED package according to this embodiment.

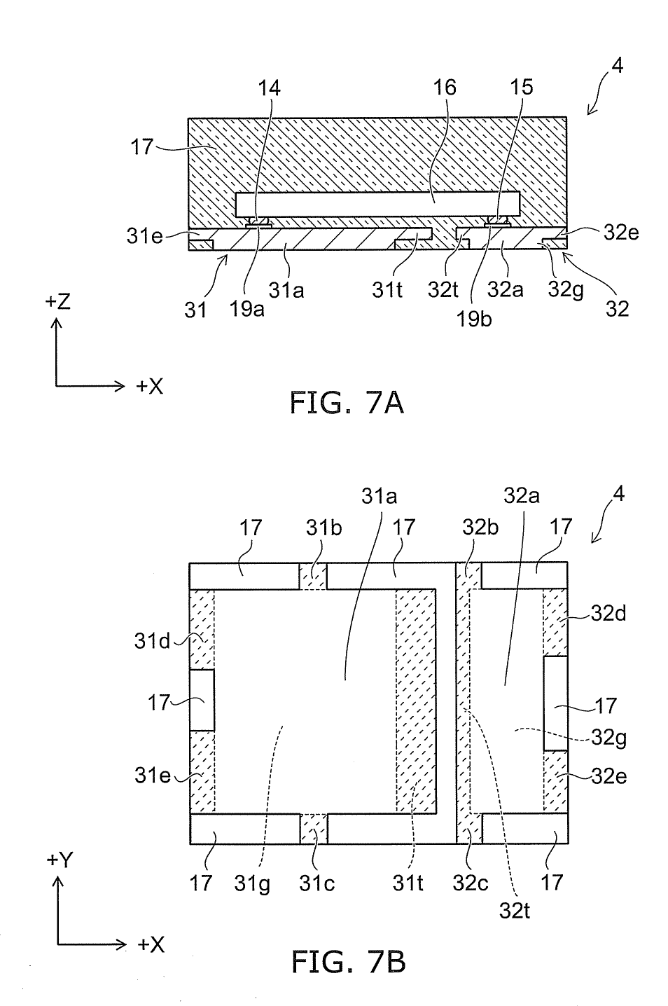

FIG. 7A is a cross-sectional view illustrating the LED package according to this embodiment; and FIG. 7B is a plan view illustrating the leadframe.

As illustrated in FIG. 6 and FIGS. 7A and 7B, the LED package 4 according to this embodiment differs from the LED package 3 (referring to FIG. 5) according to the third embodiment described above in that the configurations of the leadframes are different and the transparent resin body 17 extends around below portions of the leadframes.

The configurations of the leadframes and the positional relationship between the leadframes and the transparent resin body of this embodiment will now be described in detail.

As illustrated in FIG. 6 and FIGS. 7A and 7B, a pair of leadframes 31 and 32 is provided in the LED package 4 according to this embodiment. The leadframes 31 and 32 have flat plate configurations, are disposed in the same plane, and are separated from each other.

In the leadframe 31, one base portion 31a which is rectangular as viewed from the Z direction is provided; and four thin portions 31b, 31c, 31d, and 31e extend from the base portion 31a. The thin portion 31b extends toward the +Y direction from the X direction central portion of the end edge of the base portion 31a facing the +Y direction. The thin portion 31c extends toward the −Y direction from the X direction central portion of the end edge of the base portion 31a facing the −Y direction. The positions of the thin portions 31b and 31c are the same in the X direction. The thin portions 31d and 31e extend toward the −X direction from both end portions of the end edge of the base portion 31a facing the −X direction. Thus, the thin portions 31b to 31e extend from three mutually different sides of the base portion 31a respectively.

The length of the leadframe 32 in the X direction is shorter than the length of the leadframe 31 in the X direction; and the length of the leadframe 32 in the Y direction is the same as the length of the leadframe 31 in the Y direction. In the leadframe 32, one base portion 32a which is rectangular as viewed from the Z direction is provided; and four thin portions 32b, 32c, 32d, and 32e extend from the base portion 32a. The thin portion 32b extends toward the +Y direction from the end portion on the −X direction side of the end edge of the base portion 32a facing the +Y direction. The thin portion 32c extends toward the −Y direction from the end portion on the −X direction side of the end edge of the base portion 32a facing the −Y direction. The thin portions 32d and 32e extend toward the +X direction from both end portions of the end edge of the base portion 32a facing the +X direction. Thus, the thin portions 32b to 32e extend from three mutually different sides of the base portion 32a respectively. The widths of the thin portions 31d and 31e of the leadframe 31 may be the same as the widths of the thin portions 32d and 32e of the leadframe 32 or may be different. However, it is easy to discriminate between anode and cathode by making the widths of the thin portions 31d and 31e different from the widths of the thin portions 32d and 32e.

A protrusion 31g is formed in the X direction central portion of a lower face 31f of the leadframe 31. Therefore, the thickness of the leadframe 31 has two levels of values. The portion where the protrusion 31g is formed is a thick plate portion which is relatively thick; and the end portion of the base portion 31a on the +X direction side and the thin portions 31b to 31e are thin plate portions which are relatively thin. In FIG. 7B, the portion of the base portion 31a where the protrusion 31g is not formed is illustrated as a thin plate portion 31t.

Similarly, a protrusion 32g is formed in the X direction central portion of a lower face 32f of the leadframe 32. Thereby, the thickness of the leadframe 32 also has two levels of values. The portion where the protrusion 32g is formed is a thick plate portion which is relatively thick; and the end portion of the base portion 32a on the −X direction side and the thin portions 32b to 32e are thin plate portions which are relatively thin. In FIG. 7B, the portion of the base portion 32a where the protrusion 32g is not formed is illustrated as a thin plate portion 32t. In FIG. 7B, the thin plate portions of the leadframes 31 and 32, i.e., each of the thin plate portions and each of the thin portions, are illustrated by broken line hatching.

The protrusions 31g and 32g are formed in regions separated from the mutually-opposing end edges of the leadframes 31 and 32. The regions including these end edges are the thin plate portions 31t and 32t described above. An upper face 31h of the leadframe 31 and an upper face 32h of the leadframe 32 are in the same plane; and the lower face of the protrusion 31g of the leadframe 31 and the lower face of the protrusion 32g of the leadframe 32 are in the same plane. The position of the upper face of each of the thin portions in the Z direction matches the positions of the upper faces of the leadframes 31 and 32. Accordingly, each of the thin portions is disposed in the same XY plane.

The conductive paste 19a is bonded to the upper face 31h of the leadframe 31 to cover a portion of the region corresponding to the base portion 31a. The conductive paste 19b is bonded to the upper face 32h of the leadframe 32 to cover a portion of the region corresponding to the base portion 32a. The conductive pastes 19a and 19b are, for example, silver pastes. Similarly to the third embodiment described above, the bumps 14 and 15 are provided on the conductive pastes 19a and 19b respectively; and the LED chip 16 is provided thereon. The terminal 16a of the LED chip 16 is connected to the leadframe 31 via the bump 14 and the conductive paste 19a; and the terminal 16b of the LED chip 16 is connected to the leadframe 32 via the bump 15 and the conductive paste 19b.

In the LED package 4, the transparent resin body 17 covers the upper face, a portion of the lower face, and a portion of the end face of the leadframe 31 and the upper face, a portion of the lower face, and a portion of the end face of the leadframe 32; and the remaining portions of the lower faces and the remaining portions of the end faces are exposed. More specifically, the lower face of the protrusion 31g of the lower face 31f of the leadframe 31 is exposed at the lower face of the transparent resin body 17; and the tip faces of the thin portions 31b to 31e are exposed at the side faces of the transparent resin body 17. On the other hand, the faces of the leadframe 31 other than the lower face of the protrusion 31g and the tip faces of the thin portions 31b to 31e are covered with the transparent resin body 17. Similarly, the lower face of the protrusion 32g of the lower face 32f of the leadframe 32 is exposed at the lower face of the transparent resin body 17; and the tip faces of the thin portions 32b to 32e are exposed at the side faces of the transparent resin body 17. On the other hand, the faces of the leadframe 32 other than the lower face of the protrusion 32g and the tip faces of the thin portions 32b to 32e are covered with the transparent resin body 17. Thus, the configuration of the transparent resin body 17 is rectangular as viewed from above; and the tip faces of the multiple thin portions described above are exposed at three mutually different sides of the transparent resin body 17. In the LED package 4, the lower faces of the protrusions 31g and 32g exposed at the lower face of the transparent resin body 17 are used as external electrode pads.

Similarly to the first to third embodiments described above, many fluorescers (not illustrated) are dispersed in the interior of the transparent resin body 17. For example, a silicate-based fluorescer that emits yellowish-green, yellow, or orange light can be used as such a fluorescer. The silicate-based fluorescer can be represented by the following general formula.

(2-x-y)SrO.x(Baᵤ, Caᵥ)O.(1-a-b-c-d)SiO₂. aP₂O₅bAl₂O₃cB₂O₃dGeO₂:yEu²⁺

where 0<x, 0.005<y<0.5, x+y≦1.6, 0≦a, b, c, d<0.5, 0<u, 0<v, and u+v=1.

A YAG-based fluorescer also can be used as the yellow fluorescer. The YAG-based fluorescer can be represented by the following general formula.

(RE₁₋ₓSmₓ)₃(Al_{y}Ga_{1-y})₅O₁₂:Ce

where 0≦x<1, 0≦y≦1, and RE is at least one type of element selected from Y and Gd.

Or, a sialon-based red fluorescer and green fluorescer can be mixed and the used as the fluorescer. In other words, the fluorescer may be a green fluorescer that absorbs the blue light emitted from the LED chip 16 to emit green light and a red fluorescer that absorbs the blue light to emit red light.

The sialon-based red fluorescer can be represented by, for example, the general formula recited below.

(M₁₋ₓ, Rₓ)ₐ₁AlSi_{b1}O_{c1}N_{d1}

where M is at least one type of metal element excluding Si and Al, and it is particularly desirable for M to be at least one selected from Ca and Sr. R is a light emission center element, and it is particularly desirable for R to be Eu. Here, x, a1, b1, c1, and d1 satisfy the relationships 0<x≦1, 0.6<a1<0.95, 2<b1<3.9, 0.25<c1<0.45, and 4<d1<5.7.

A specific example of such a sialon-based red fluorescer is as follows.

Sr₂Si₇Al₇ON₁₃:Eu²⁺

The sialon-based green fluorescer can be represented by, for example, the general formula recited below.

(M₁₋ₓ, Rₓ)ₐ₂AlSi_{b2}O_{c2}N_{d2}

where M is at least one type of metal element excluding Si and Al, and it is particularly desirable for M to be at least one selected from Ca and Sr. R is a light emission center element, and it is particularly desirable for R to be Eu. Here, x, a2, b2, c2, and d2 satisfy the relationships 0<x≦1, 0.93<a2<1.3, 4.0<b2<5.8, 0.6<c2<1, and 6<d2<11.

A specific example of such a sialon-based green fluorescer is as follows.

Sr₃Si₁₃Al₃O₂N₂₁:Eu²⁺

A method for manufacturing the LED package according to this embodiment will now be described.

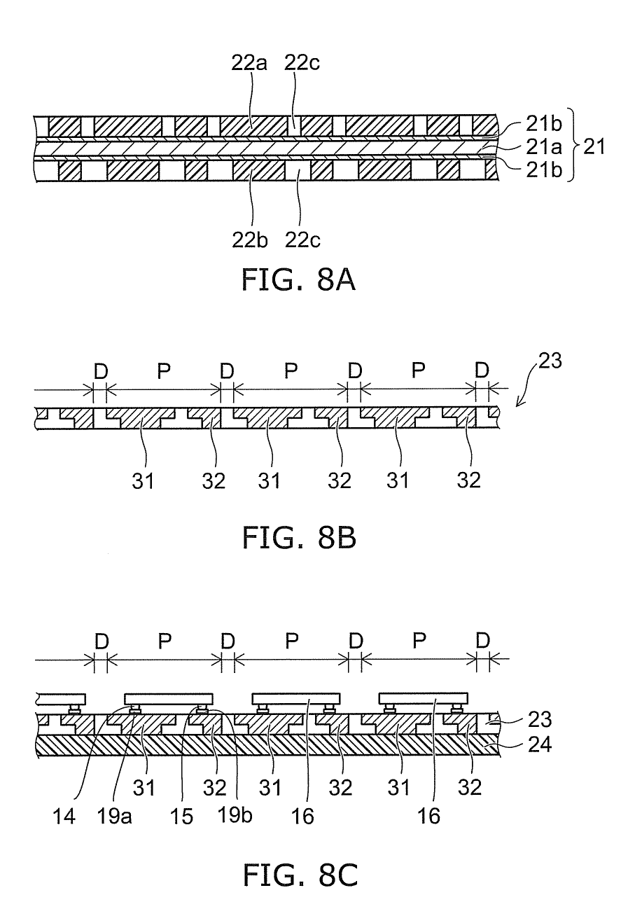

FIGS. 8A to 8C, FIGS. 9A to 9C, and FIGS. 10A and 10B are cross-sectional views of processes, illustrating the method for manufacturing the LED package according to this embodiment.

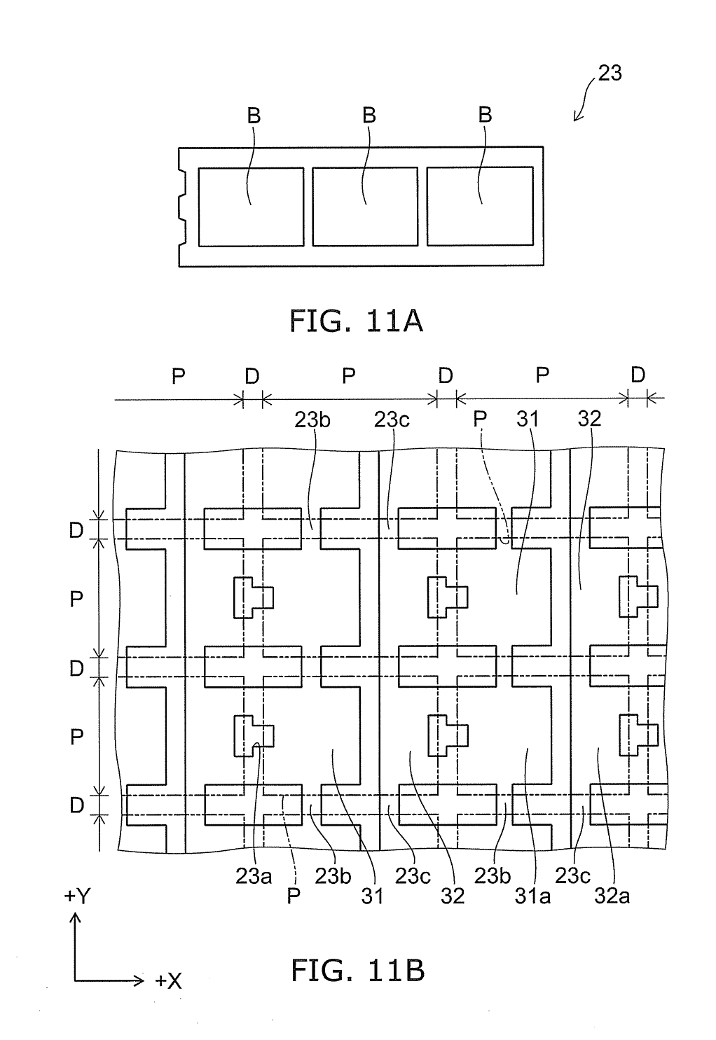

FIG. 11A is a plan view illustrating the leadframe sheet of this embodiment; and FIG. 11B is a partially enlarged plan view illustrating device regions of the leadframe sheet.

First, as illustrated in FIG. 8A, a conductive sheet 21 made of a conductive material is prepared. The conductive sheet 21 includes, for example, silver plating layers 21b formed on the upper face and the lower face of a copper plate 21a having a rectangular configuration. Then, masks 22a and 22b are formed on the upper face and the lower face of the conductive sheet 21. Openings 22c are made selectively in the masks 22a and 22b. The masks 22a and 22b may be formed using, for example, printing.

Wet etching is performed on the conductive sheet 21 by immersing the conductive sheet 21, which is covered with the masks 22a and 22b bonded thereto, in an etchant. Thereby, the portion of the conductive sheet 21 positioned inside the opening 22c is selectively removed by etching. At this time, the etching amount is controlled by adjusting, for example, the immersion time; and the etching is stopped before the etching from the upper face side of the conductive sheet 21 or the etching from the lower face side of the conductive sheet 21 independently pierces the conductive sheet 21. Thereby, half-etching is performed from the upper face side and the lower face side. However, portions etched from both the upper face side and the lower face side pierce the conductive sheet 21. Subsequently, the masks 22a and 22b are removed.

Thereby, as illustrated in FIG. 8B, the copper plate 21a and the silver plating layer 21b are selectively removed from the conductive sheet 21 to form a leadframe sheet 23. For convenience of illustration in FIG. 8B and subsequent drawings, the copper plate 21a and the silver plating layer 21b are illustrated integrally as the leadframe sheet 23 without being discriminated. In the leadframe sheet 23 as illustrated in FIG. 11A, for example, three blocks B are set; and, for example, about 1000 device regions P are set in each of the blocks B. As illustrated in FIG. 11B, the device regions P are arranged in a matrix configuration; and the region between the device regions P is used as a dicing region D having a lattice configuration. A basic pattern including the mutually-separated leadframes 31 and 32 is formed in each of the device regions P. In the dicing region D, the conductive material of the conductive sheet 21 remains to link mutually adjacent device regions P to form a conductive member provided across the dicing region D.

In other words, although the leadframe 31 and the leadframe 32 are mutually separated in the device region P, the leadframe 31 belonging to one of the device regions P is linked to the leadframe 32 belonging to the adjacent device region P positioned in the −X direction as viewed from the one of the device regions P; and an opening 23a having an inverted-T shaped configuration facing the +X direction is made between the two frames. The leadframes 31 belonging to the device regions P adjacent to each other in the Y direction are linked to each other via the bridge 23b. Similarly, the leadframes 32 belonging to the device regions P adjacent to each other in the Y direction are linked to each other via a bridge 23c. Thereby, four conductive members extend toward three directions from the base portions 31a and 32a of the leadframes 31 and 32. The protrusions 31g and 32g (referring to FIGS. 7A and 7B) are formed on the lower faces of the leadframes 31 and 32 respectively by the etching from the lower face side of the leadframe sheet 23 being half-etching.

Then, as illustrated in FIG. 8C, a reinforcing tape 24 made of, for example, polyimide is adhered to the lower face of the leadframe sheet 23. Continuing, the conductive pastes 19a and 19b are bonded to the leadframe 31 belonging to each of the device regions P of the leadframe sheet 23 to cover the leadframe 31. Then, the LED chip 16 which includes the bumps 14 and 15 bonded to the terminals 16a and 16b respectively is mounted on each of the device regions P of the leadframe sheet 23. At this time, the bump 14 is bonded to the conductive paste 19a; and the bump 15 is bonded to the conductive paste 19b. Thereby, the terminal 16a of the LED chip 16 is connected to the leadframe 31 via the bump 14 and the conductive paste 19a; and the terminal 16b is connected to the leadframe 32 via the bump 15 and a conductive paste 23b.

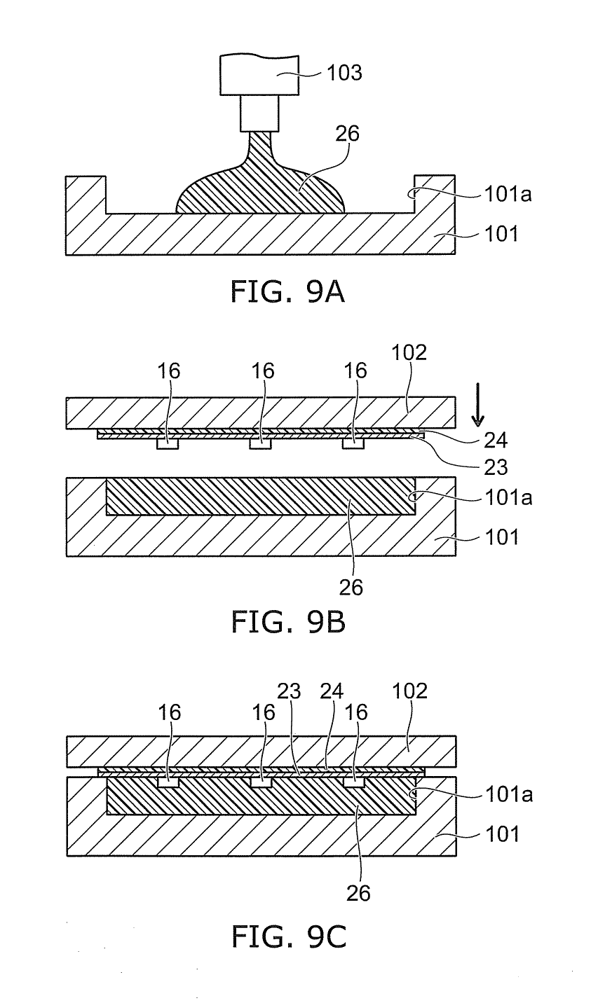

Continuing as illustrated in FIG. 9A, a lower die 101 is prepared. The lower die 101 is included in one die set with an upper die 102 described below; and a recess 101a having a rectangular parallelepiped configuration is made in the upper face of the lower die 101. On the other hand, a liquid or semi-liquid fluorescer-containing resin material 26 is prepared by mixing fluorescers (not illustrated) into a transparent resin such as a silicone resin and stirring. Then, the fluorescer-containing resin material 26 is supplied to the recess 101a of the lower die 101 using a dispenser 103.

Then, as illustrated in FIG. 9B, the leadframe sheet 23 on which the LED chips 16 described above are mounted is mounted on the lower face of the upper die 102 such that the LED chips 16 face downward. Then, the upper die 102 is pressed onto the lower die 101; and the die is dosed. Thereby, the leadframe sheet 23 is pressed onto the fluorescer-containing resin material 26. At this time, the fluorescer-containing resin material 26 covers the LED chip 16, the bumps 14 and 15, and the conductive pastes 19a and 19b and enters also into the portion of the leadframe sheet 23 removed by the etching. Thus, the fluorescer-containing resin material 26 is molded. It is favorable for the mold process to be implemented in a vacuum atmosphere. This prevents bubbles that occur in the fluorescer-containing resin material 26 from adhering to the half-etched portions of the leadframe sheet 23.

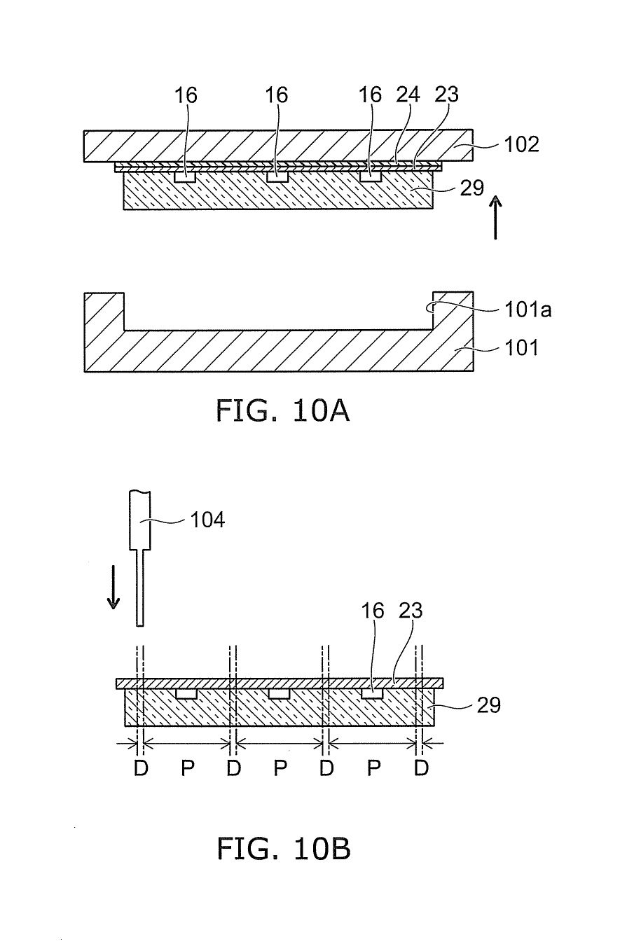

Continuing as illustrated in FIG. 9C, heat treatment is performed in a state in which the upper face of the leadframe sheet 23 is pressed onto the fluorescer-containing resin material 26 to cure the fluorescer-containing resin material 26. Subsequently, as illustrated in FIG. 10A, the upper die 102 is pulled away from the lower die 101. Thereby, a transparent resin plate 29 is formed on the leadframe sheet 23 to cover the entire upper face and a portion of the lower face of the leadframe sheet 23 to bury the LED chip 16, etc. Fluorescers (not illustrated) are dispersed in the transparent resin plate 29. Subsequently, the reinforcing tape 24 is peeled from the leadframe sheet 23. Thereby, the lower faces of the protrusions 31g and 32g (referring to FIGS. 7A and 7B) of the leadframes 31 and 32 are exposed at the surface of the transparent resin plate 29.

Then, as illustrated in FIG. 10B, dicing is performed on the bonded body made of the leadframe sheet 23 and the transparent resin plate 29 from the leadframe sheet 23 side using a blade 104. In other words, dicing is performed toward the +Z direction. Thereby, the portions of the leadframe sheet 23 and the transparent resin plate 29 disposed in the dicing region D are removed. As a result, the portions of the leadframe sheet 23 and the transparent resin plate 29 disposed in the device regions P are singulated; and the LED package 4 illustrated in FIG. 6 and FIGS. 7A and 7B is manufactured.

The leadframes 31 and 32 are separated from the leadframe sheet 23 in each of the LED packages 4 after the dicing. The transparent resin plate 29 is divided to form the transparent resin body 17. The thin portions 31d and 31e and the thin portions 32d and 32e are formed in the leadframes 31 and 32 respectively by the portion of the dicing region D that extends in the Y direction passing through the openings 23a of the leadframe sheet 23. The thin portions 31b and 31c are formed in the leadframe 31 by the bridge 23b being divided; and the thin portions 32b and 32c are formed in the leadframe 32 by the bridge 23c being divided. The tip faces of the thin portions 31b to 31e and 32b to 32e are exposed at the side faces of the transparent resin body 17.

Operational effects of this embodiment will now be described.

In the LED package 4 according to this embodiment, the peripheral portion of the leadframes 31 and 32 is held by the transparent resin body 17 covering a portion of the lower faces and the greater part of the end faces of the leadframes 31 and 32. Therefore, the holdability of the leadframes 31 and 32 can be increased while realizing the external electrode pads in which the lower faces of the protrusions 31g and 32g of the leadframes 31 and 32 are exposed from the transparent resin body 17. In other words, the leadframes 31 and 32 can be securely held by the transparent resin body 17 extending around below each of the thin portions and each of the thin plate portions of the leadframes 31 and 32. Thereby, the leadframes 31 and 32 do not easily peel from the transparent resin body 17 during the dicing; and the yield of the LED package 4 can be increased. Further, the leadframes 31 and 32 can be prevented from peeling from the transparent resin body 17 due to thermal stress when the manufactured LED package 4 is being used.

In this embodiment, many, e.g., about several thousand LED packages 4 can be collectively manufactured from one conductive sheet 21. Thereby, the cost of manufacturing one LED package can be reduced.

In this embodiment, the leadframe sheet 23 is formed using wet etching. Therefore, it is sufficient to prepare a master form for only the mask when manufacturing an LED package with a new layout; and the initial cost can be lower than that of the case where the leadframe sheet 23 is formed using a method such as stamping using a die.

In the LED package 4 according to this embodiment, the thin portions extend from the base portions 31a and 32a of the leadframes 31 and 32 respectively. Thereby, the base portion itself is prevented from being exposed at the side faces of the transparent resin body 17; and the exposed surface area of the leadframes 31 and 32 can be reduced. Further, the contact surface area between the transparent resin body 17 and the leadframes 31 and 32 can be increased. As a result, the leadframes 31 and 32 can be prevented from peeling from the transparent resin body 17. Corrosion of the leadframes 31 and 32 also can be suppressed.

In the leadframe sheet 23 as illustrated in FIG. 11B, the metal portions interposed in the dicing region D are reduced by providing the opening 23a and the bridges 23b and 23c to be interposed in the dicing region D. Thereby, the dicing is easier; and wear of the dicing blade can be suppressed.

In this embodiment, four thin portions extend in three directions from each of the leadframes 31 and 32. Thereby, the mountability is high because the leadframes 31 and 32 are supported reliably from three directions by the leadframes 31 and 32 of the adjacent device regions P in the mount process of the LED chip 16 illustrated in FIG. 8C.

In this embodiment, the dicing is performed from the leadframe sheet 23 side in the dicing process illustrated in FIG. 10B. Thereby, the metal material of the cutting end portions of the leadframes 31 and 32 elongates over the side face of the transparent resin body 17 in the +Z direction. Therefore, this metal material does not elongate over the side face of the transparent resin body 17 in the −Z direction to protrude from the lower face of the LED package 4; and burrs do not occur. Accordingly, mounting defects due to burrs do not occur when mounting the LED package 4.

Otherwise, the configuration and effects of this embodiment are similar to those of the third embodiment described above.

A first variation of the fourth embodiment will now be described.

This variation is a variation of the formation method of the leadframe sheet.

Namely, in this variation, the formation method of the leadframe sheet illustrated in FIG. 8A differs from that of the first embodiment described above.

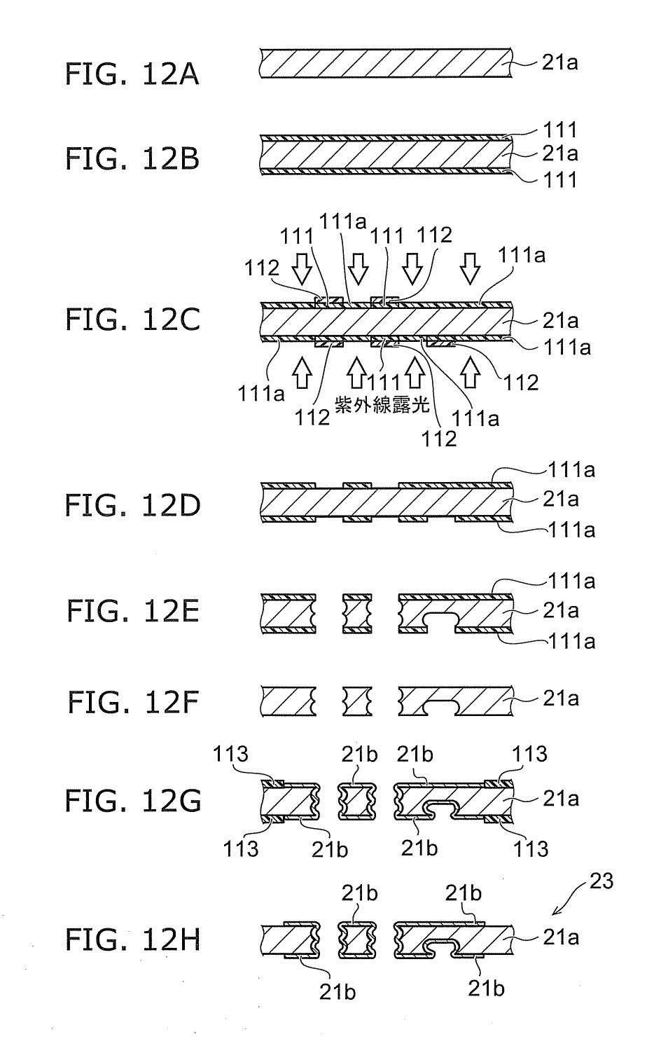

FIGS. 12A to 12H are cross-sectional views of processes, illustrating the formation method of the leadframe sheet of this variation.

First, as illustrated in FIG. 12A, a copper plate 21a is prepared and cleaned. Then, as illustrated in FIG. 12B, a resist coating is formed on both faces of the copper plate 21a and subsequently dried to form a resist film 111. Continuing as illustrated in FIG. 12C, exposure is performed by disposing a mask pattern 112 on the resist film 111 and irradiating ultraviolet rays. Thereby, the exposed portion of the resist film 111 is cured to form a resist mask 111a. Then, as illustrated in FIG. 12D, development is performed to wash away the uncured portion of the resist film 111. Thereby, the resist pattern 111a remains on the upper face and the lower face of the copper plate 21a. Then, as illustrated in FIG. 12E, etching is performed using the resist pattern 111a as a mask to remove the exposed portion from both faces of the copper plate 21a. At this time, the etching depth is about half of the plate thickness of the copper plate 21a. Thereby, the regions etched only from the side of one face are half-etched; and the regions etched from the sides of both faces are pierced through. Continuing as illustrated in FIG. 12F, the resist pattern 111a is removed. Then, as illustrated in FIG. 12G, the end portions of the copper plate 21a are covered with a mask 113 and plating is performed. Thereby, the silver plating layer 21b is formed on the surfaces of the portions other than the end portions of the copper plate 21. Then, as illustrated in FIG. 12H, cleaning is performed to remove the mask 113. Subsequently, an inspection is performed. Thus, the leadframe sheet 23 is constructed. Otherwise, the configuration, manufacturing method, and operational effects of this variation are similar to those of the fourth embodiment described above.

A second variation of the fourth embodiment will now be described.

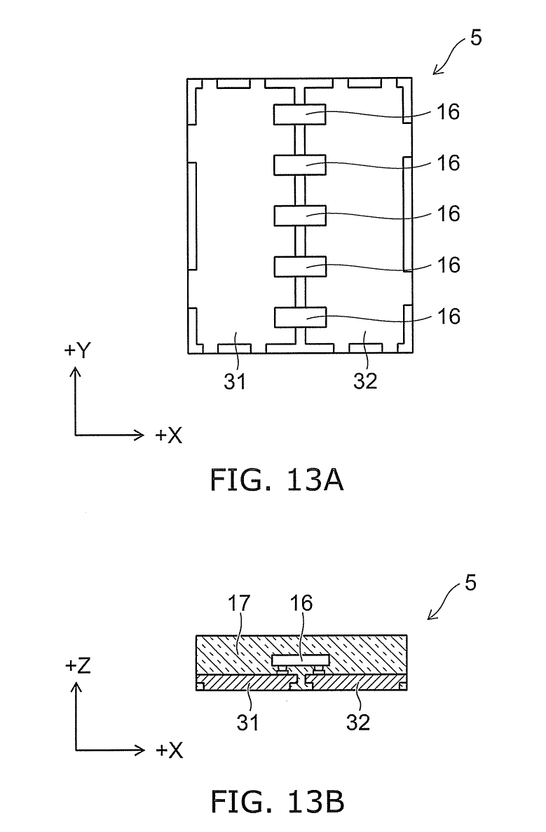

FIG. 13A is a plan view illustrating an LED package according to this variation; and FIG. 13B is a cross-sectional view of FIG. 13A.

As illustrated in FIGS. 13A and 13B, the LED package 5 according to this variation differs from the LED package 4 (referring to FIG. 6) according to the fourth embodiment described above in that five flip-type LED chips 16 are provided. Similarly to the fourth embodiment, each of the LED chips 16 is provided in a bridge-like configuration straddling the leadframe 31 and the leadframe 32; the terminal 16a connected to the leadframe 31; and the terminal 16b connected to the leadframe 32. Thereby, five LED chips 16 are connected in parallel with each other between the leadframe 31 and the leadframe 32. Thereby, according to this variation, an emitted light which is more intense than that of the fourth embodiment described above can be obtained. Otherwise, the configuration, manufacturing method, and operational effects of this variation are similar to those of the fourth embodiment described above.

Although an example is illustrated in the fourth embodiment and the variations thereof described above in which the leadframe sheet 23 is formed using wet etching, the invention is not limited thereto. For example, mechanical means such as a press may be used to form the leadframe sheet 23. Although an example is illustrated in the embodiments and the variations thereof described above in which the silver plating layers are formed on the upper face and the lower face of the copper plate of the leadframe, the invention is not limited thereto. For example, silver plating layers may be formed on the upper face and the lower face of the copper plate; and a rhodium (Rh) plating layer may be formed on at least one of the silver plating layers. A copper (Cu) plating layer may be formed between the copper plate and the silver plating layer. A nickel (Ni) plating layer may be formed on the upper face and the lower face of the copper plate; and a plating layer of an alloy of gold and silver (a Au—Ag alloy) may be formed on the nickel plating layer.

It is possible to practice the fourth embodiment and the variations thereof described above in combination with the second embodiment described above. In other words, the anisotropic conductive paste 18 may be provided instead of the conductive pastes 19a and 19b.

Although an example is illustrated in the embodiments and the variations thereof described above in which the LED chip emits blue light, the fluorescer absorbs the blue light to emit yellow light, and the color of the light emitted from the LED package is white, the invention is not limited thereto. The LED chip may emit visible light other than blue light, ultraviolet rays, or infrared rays. The fluorescer is not limited to emitting yellow light and may emit, for example, blue light, green light, or red light.

Although an example is illustrated in the embodiments and the variations thereof described above in which the base portion of the leadframe has a rectangular configuration as viewed from above, the configuration of the base portion may be a configuration in which at least one corner is removed. Thereby, such corners do not serve as starting points for resin peeling and cracking because right angles or acute angles proximal to the corners of the LED package have been removed. As a result, the occurrence of resin peeling and cracking can be suppressed for the LED package as an entirety.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions. Further, the embodiments described above may be implemented in combination.

According to the embodiments described above, an LED package can be realized in which the light extraction efficiency is high.

What is claimed is:

1. An LED package, comprising:
a first leadframe and a second leadframe mutually separated;
an anisotropic conductive film provided on the first leadframe and the second leadframe;
an LED chip provided on the anisotropic conductive film, the LED chip including a first terminal and a second terminal provided on a face of the LED chip on the anisotropic conductive film side; and
a resin body provided on the anisotropic conductive film to cover the LED chip,
the first terminal being connected to the first leadframe via the anisotropic conductive film, the second terminal being connected to the second leadframe via the anisotropic conductive film.

2. The LED package according to claim 1, further comprising
a first bump to connect the first terminal to the anisotropic conductive film, and
a second bump to connect the second terminal to the anisotropic conductive film.

3. The LED package according to claim 1, wherein an exterior form of a portion of the package positioned above the anisotropic conductive film is an exterior form of the resin body.

4. The LED package according to claim 1, wherein the resin body covers an upper face, a portion of a lower face, and a portion of an end face of the first leadframe and an upper face, a portion of a lower face, and a portion of an end face of the second leadframe, a remaining portion of the lower faces of the first leadframe and the second leadframe and a remaining portion of the end faces of the first leadframe and the second leadframe being exposed.

5. The LED package according to claim 1, wherein
protrusions are formed on a lower face of the first leadframe and a lower face of the second leadframe, the protrusions being formed in regions separated from mutually-opposing end edges of the lower faces of the first leadframe and the second leadframe, and
lower faces of the protrusions are exposed at a lower face of the resin body, and side faces of the protrusions are covered with the resin body.

6. The LED package according to claim 1, wherein
the first leadframe includes:
a base portion having an end face covered with the resin body; and
a thin portion extending from the base portion, a lower face of the thin portion being covered with the resin body, a tip face of the thin portion being exposed at a side face of the resin body.

7. The LED package according to claim 6, wherein three of the thin portions are provided, and the three thin portions are exposed at three mutually different side faces of the resin body.

8. The LED package according to claim 1, wherein:
at least one selected from the first leadframe and the second leadframe includes
a base portion having an end face covered with the resin body and
three thin portions extended in mutually different directions from the base portion, lower faces of the three thin portions being covered with the resin body, tip faces of the three thin portions being exposed at a side face of the resin body;
a protrusion is formed on one selected from a lower face of the first leadframe and a lower face of the second leadframe, the protrusion being formed in a region separated from one other selected from the lower face of the first leadframe and the lower face of the second leadframe, a lower face of the protrusion being exposed at a lower face of the resin body, a side face of the protrusion being covered with the resin body; and
an exterior form of the resin body is used as an exterior form of the package.

9. An LED package, comprising:
a first leadframe and a second leadframe mutually separated;
a conductive paste provided on the first leadframe and the second leadframe;
an LED chip provided on the conductive paste, the LED chip including a first terminal and a second terminal provided on a face of the LED chip on the conductive paste side; and
a resin body covering the LED chip.

10. The LED package according to claim 9, wherein
the conductive paste is an anisotropic conductive paste, and
the first terminal is connected to the first leadframe via one portion of the anisotropic conductive paste, and the second terminal is connected to the second leadframe via one other portion of the anisotropic conductive paste.

11. The LED package according to claim 9, wherein:
the conductive paste includes
a first portion provided on the first leadframe, and
a second portion provided on the second leadframe and separated from the first portion; and
the first terminal is connected to the first leadframe via the first portion, and the second terminal is connected to the second leadframe via the second portion.

12. The LED package according to claim 9, further comprising:
a first bump connected to the first terminal; and
a second bump connected to the second terminal.

13. The LED package according to claim 9, wherein an exterior form of a portion of the package positioned above the first leadframe and the second leadframe is an exterior form of the resin body.

14. The LED package according to claim 9, wherein the resin body covers an upper face, a portion of a lower face, and a portion of an end face of the first leadframe and an upper face, a portion of a lower face, and a portion of an end face of the second leadframe, a remaining portion of the lower faces of the first leadframe and the second leadframe and a remaining portion of the end faces of the first leadframe and the second leadframe being exposed.

15. The LED package according to claim 9, wherein
protrusions are formed on a lower face of the first leadframe and a lower face of the second leadframe, the protrusions being formed in regions separated from mutually-opposing end edges of the lower faces of the first leadframe and the second leadframe, and
lower faces of the protrusions are exposed at a lower face of the resin body, and side faces of the protrusions are covered with the resin body.

16. The LED package according to claim 9, wherein
the first leadframe includes:
a base portion having an end face covered with the resin body; and
a thin portion extending from the base portion, a lower face of the thin portion being covered with the resin body, a tip face of the thin portion being exposed at a side face of the resin body.

17. The LED package according to claim 16, wherein at least three of the thin portions are provided, and the at least three thin portions are exposed at three mutually different side faces of the resin body.

18. The LED package according to claim 9, wherein:
at least one selected from the first leadframe and the second leadframe includes
a base portion having an end face covered with the resin body, and
three thin portions extended in mutually different directions from the base portion, lower faces of the three thin portions being covered with the resin body, tip faces of the three thin portions being exposed at a side face of the resin body;
a protrusion is formed on one selected from a lower face of the first leadframe and a lower face of the second leadframe, the protrusion being formed in a region separated from one other selected from the lower face of the first leadframe and the lower face of the second leadframe, a lower face of the protrusion being exposed at a lower face of the resin body, a side face of the protrusion being covered with the resin body; and
an exterior form of the resin body is used as an exterior form of the package.
